(19) United States
(12) Patent Application Publication
(10) Pub. No.: US 2015/0048317 A1
(43) Pub. Date: Feb. 19, 2015

(54) SOLID STATE IMAGING DEVICE

(71) Applicant: KABUSHIKI KAISHA TOSHIBA, Tokyo (JP)

(72) Inventor: Hiroki SASAKI, Yokohama-shi (JP)

(73) Assignee: KABUSHIKI KAISHA TOSHIBA, Tokyo (JP)

(21) Appl. No.: 14/102,460

(22) Filed: Dec. 10, 2013

(30) Foreign Application Priority Data
Aug. 13, 2013 (JP) 2013-168323

(51) Int. Cl. H01L 27/28; H01L 27/30

(52) U.S. Cl. CPC H01L 27/286; H01L 27/307
USPC 257/40

(57) ABSTRACT

According to one embodiment, solid state imaging device includes, a semiconductor substrate and a photoelectric conversion unit formed in the semiconductor substrate or above the semiconductor substrate. Further, the photoelectric conversion unit is provided with a first photoelectric conversion unit and a second photoelectric conversion unit. One of the first and second photoelectric conversion unit uses at least a part of the semiconductor substrate as a first photoelectric conversion layer, and the other of the first and second photoelectric conversion unit uses an inorganic semiconductor material that is of a different type from the semiconductor substrate as a second photoelectric conversion layer. The second photoelectric conversion unit photoelectrically converts light in a wavelength range that had permeated the first photoelectric conversion unit.

### CROSS-REFERENCE TO RELATED APPLICATIONS

This application is based upon and claims the benefit of priority from Japanese Patent Application No. 2013-168323, filed on Aug. 13, 2013; the entire contents of which are incorporated herein by reference.

### FIELD

The embodiments of the invention relate to a solid state imaging device.

### BACKGROUND

Recently, a technique of a solid state imaging device that photoelectrically converts incident light by using a photoelectric conversion film and that can extract light signals of three primary colors by one pixel has been disclosed.

As a conventional solid state imaging device, for example, a method that performs photoelectric conversion respectively for light of the three primary colors in each pixel by arranging the pixels corresponding to the three primary colors of RGB on a plane is generally used. In a pixel arrangement in the plane, a Bayer array in which two pixels of G (green) pixels are arranged diagonally, and one pixel each of R (red) pixel and B (blue) pixel is arranged is generally used. In this type of solid state imaging device, since detection is performed at different positions, there is a problem that color separation and false color occur in an output image and image quality deterioration is caused thereby. In order to avoid such image quality deterioration, a laminate type pixel structure that laminates pixels for detecting the three primary colors of RGB is being proposed. In such a solid state imaging device, photoelectric conversion units for B light reception, G light reception, and R light reception are laminated in Si as seen from a light incident surface. Since color separation in such a pixel structure is performed by using wavelength dependency of optical absorption constants, color mixture may occur in some cases between R and G, G and B, and R and B, respectively.

Regarding the problem of color mixture unique to the laminated type pixel structure, a structure that reduces color mixture of R and G, as well as G and B by forming the photoelectric conversion unit for G light reception in a vicinity of a wiring layer, and performing photoelectric conversion of G prior to R and B is proposed. However, in such a structure, color mixture of R and B cannot be reduced. Further, such a device structure uses a structure that laminates photo diodes as the photoelectric conversion units, in which the photo diodes are laminated on a thick Si substrate, it requires an implant apparatus with very high acceleration. Further, since a very thick, special hard mask is required in an ion injection step using the implant apparatus with very high acceleration, a complicated process becomes necessary.

### BRIEF DESCRIPTION OF THE DRAWINGS

FIG. 1 is a cross sectional diagram schematically illustrating a configuration of a photoelectric conversion unit of a solid state imaging device of a first embodiment;

FIG. 2 is a diagram illustrating spectral sensitivity characteristics of quinacridone used in the photoelectric conversion unit of the solid state imaging device of the first embodiment;

FIG. 3 is a diagram illustrating spectral sensitivity characteristics of silicon used in the photoelectric conversion unit of the solid state imaging device of the first embodiment;

FIG. 4 is a diagram illustrating spectral sensitivity characteristics of germanium used in the photoelectric conversion unit of the solid state imaging device of the first embodiment;

FIGS. 5A and 5B are a cross sectional diagram and a planar diagram schematically illustrating a configuration of a solid state imaging device of a second embodiment, where an A-A cross section in FIG. 5B corresponds to a right-side portion of a pixel region R₁ in FIG. 5A, and a B-B cross section in FIG. 5B corresponds to a left-side portion of the pixel region R₁ in FIG. 5A;

FIGS. 6A and 6B are a cross sectional diagram and a planar diagram schematically illustrating a configuration of a solid state imaging device of a third embodiment, where an A-A cross section in FIG. 6B corresponds to a right-side portion of a pixel region R₁ in FIG. 6A, and a B-B cross section in FIG. 6B corresponds to a left-side portion of the pixel region R₁ in FIG. 6A;

FIG. 7 is a diagram illustrating a relationship of bias voltage and quantum efficiency;

FIGS. 8A and 8B are a cross sectional diagram and a planar diagram schematically illustrating a configuration of a solid state imaging device of a fourth embodiment, where an A-A cross section in FIG. 8B corresponds to a right-side portion of a pixel region R₁ in FIG. 8A, and a B-B cross section in FIG. 8B corresponds to a left-side portion of the pixel region R₁ in FIG. 8A;

FIGS. 9A to 9J are process cross sectional diagrams each illustrating a manufacturing step of the solid state imaging device of the fourth embodiment;

FIG. 10 is a cross sectional diagram schematically illustrating a configuration of a photoelectric conversion unit of a solid state imaging device of a fifth embodiment.

### DETAILED DESCRIPTION

One embodiment of the invention includes: a semiconductor substrate including a first principal surface configuring a light receiving surface and a second principal surface opposing the first principal surface; and a photoelectric conversion unit formed in the semiconductor substrate or above the semiconductor substrate, and configured to photoelectrically convert entered light to signal charges. Further, the photoelectric conversion unit includes: a first photoelectric conversion unit that uses at least a part of the semiconductor substrate as a first photoelectric conversion layer; and a second photoelectric conversion unit that is formed on the second principal surface side of the semiconductor substrate and uses an inorganic semiconductor material that is of a different type from the semiconductor substrate as a second photoelectric conversion layer. The second photoelectric conversion unit photoelectrically converts light in a wavelength range having permeated the first photoelectric conversion unit from the first principal surface side.

Hereinbelow, a solid state imaging device according to embodiments will be described in detail with reference to the drawings. Notably, the invention is not limited by these embodiments.

### First Embodiment

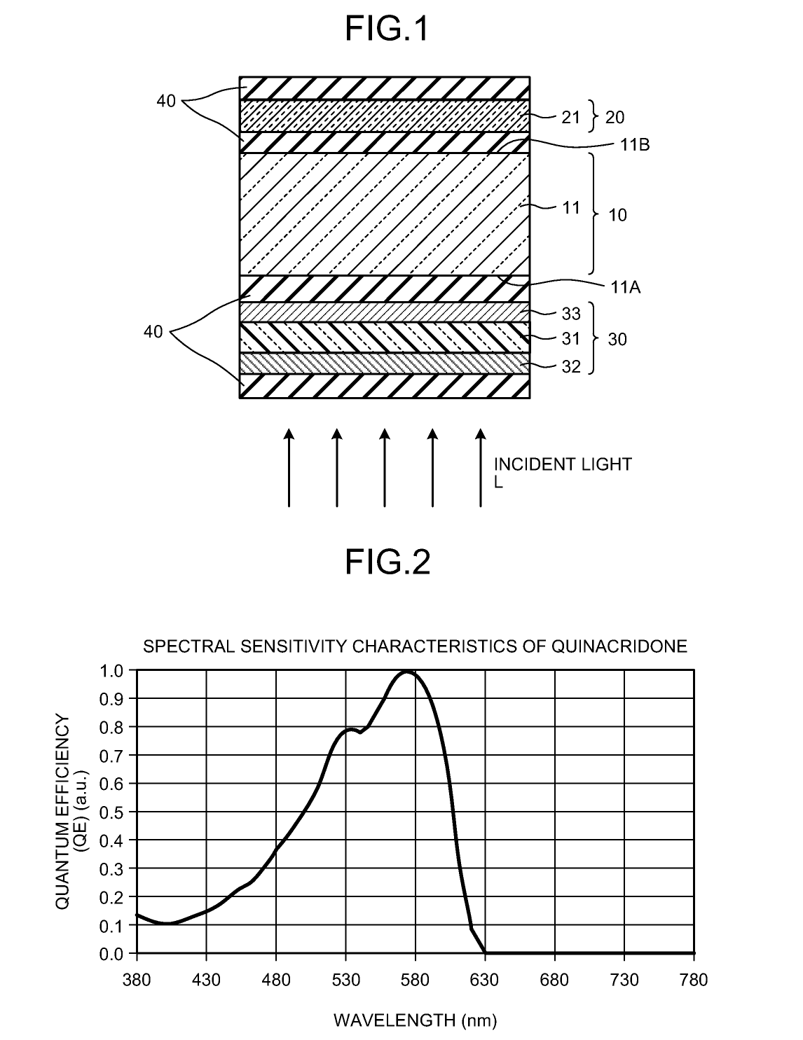

A solid state imaging device of the embodiment includes a photoelectric conversion unit that photoelectrically converts entered light to signal charges, and a transfer unit that transfers the signal charge generated in the photoelectric conversion unit from the photoelectric conversion unit to a floating diffusion unit, is configured to output an image signal, and has characteristics in the photoelectric conversion unit. FIG. 1 is a cross sectional diagram schematically illustrating a configuration of the photoelectric conversion unit of the solid state imaging device of the first embodiment. The photoelectric conversion unit of the solid state imaging device includes a first photoelectric conversion unit 10 that uses a semiconductor substrate configured of a monocrystal silicon substrate 11 with a thickness of 0.5 μm as a first photoelectric conversion layer, a second photoelectric conversion unit 20 that is formed on a second principal surface 11B side opposing a first principal surface 11A configuring a light receiving surface of the monocrystal silicon substrate 11, and uses a silicon germanium (SiGe) layer 21 that is of a semiconductor material of a different type from the semiconductor substrate as a second photoelectric conversion layer, and a third photoelectric conversion unit 30 that uses an organic film 31 configured of quinacridone applied on a first principal surface side as a third photoelectric conversion layer, and each of the photoelectric conversion units is covered by interlayer insulating films 40 such as silicon oxide films.

The third photoelectric conversion unit 30 positioned on a light receiving surface side is configured of the organic film 31 sandwiched by first and second electrodes 32, 33, and photoelectrically converts green (G) light with wavelength of 500 nm to 600 nm among light L having entered from a first principal surface 11A side. Further, blue (B) light in a wavelength range of wavelength of 300 nm to 500 nm having permeated the third photoelectric conversion unit 30 is selectively absorbed and photoelectrically converted at the first photoelectric conversion unit 10 formed in the monocrystal silicon substrate 11. Further, the first photoelectric conversion unit 10 works as a light filter and removes light with wavelength of 300 nm to 500 nm having entered from the first principal surface 11A side and selectively absorbed by the first photoelectric conversion unit 10, and the second photoelectric conversion unit 20 photoelectrically converts red (R) light in a long wavelength region of wavelength of 600 nm or more, selectively.

Here, the first photoelectric conversion unit 10 is configured to form a pn junction at a desired depth in the monocrystal silicon substrate 11, and perform signal extraction by an electrode that is not illustrated.

The second photoelectric conversion unit 20 is configured of the silicon germanium layer 21 as the second photoelectric conversion layer deposited by a CVD method and the like via the interlayer insulating film 40 on the second principal surface 11B of the monocrystal silicon substrate 11, and electrodes that are not illustrated and sandwiching the silicon germanium layer 21.

The third photoelectric conversion unit 30 is configured of the organic film 31 configured of quinacridone as the third photoelectric conversion layer formed by an application method and the like via the interlayer insulating film 40 on the first principal surface 11A of the monocrystal silicon substrate 11, and the first and second electrodes 32, 33 configured of translucent conductive films such as ITO and the like sandwiching the organic film 31.

A wiring unit that extracts outputs of the first to third photoelectric conversion units 10, 20, 30 and performs signal processing is provided on a second principal surface 11B side, however, such is omitted herein. Notably, in a case where a light shielding film that defines the light receiving region is provided, the wiring unit may be formed in a region covered by the light shielding film on the first principal surface 11A side. Further, it may be formed on the second principal surface 11B side as well as on the first principal surface 11A side, thereby on both surfaces.

Next, an imaging principle of the solid state imaging device of the embodiment will be described. The incident light L firstly enters the third photoelectric conversion unit 30. The organic film 31 configuring the third photoelectric conversion unit 30 has its both surfaces sandwiched by the first and second electrodes 32, 33, and a photoelectric conversion of the light with the wavelength of 500 nm to 600 nm, that is, the green light is performed. FIG. 2 illustrates spectral sensitivity characteristics of the quinacridone. A horizontal axis indicates the wavelength (nm), and a vertical axis indicates sensitivity in quantum efficiency. As is apparent from FIG. 2, the quinacridone has the wavelength of 580 nm as a peak wavelength, and exhibits high sensitivity in the vicinity thereof.

Further, the light having permeated the third photoelectric conversion unit 30 that uses the organic film 31 configured of the quinacridone as the third photoelectric conversion layer is photoelectrically converted by the first photoelectric conversion unit 10 configured of the monocrystal silicon substrate 11.

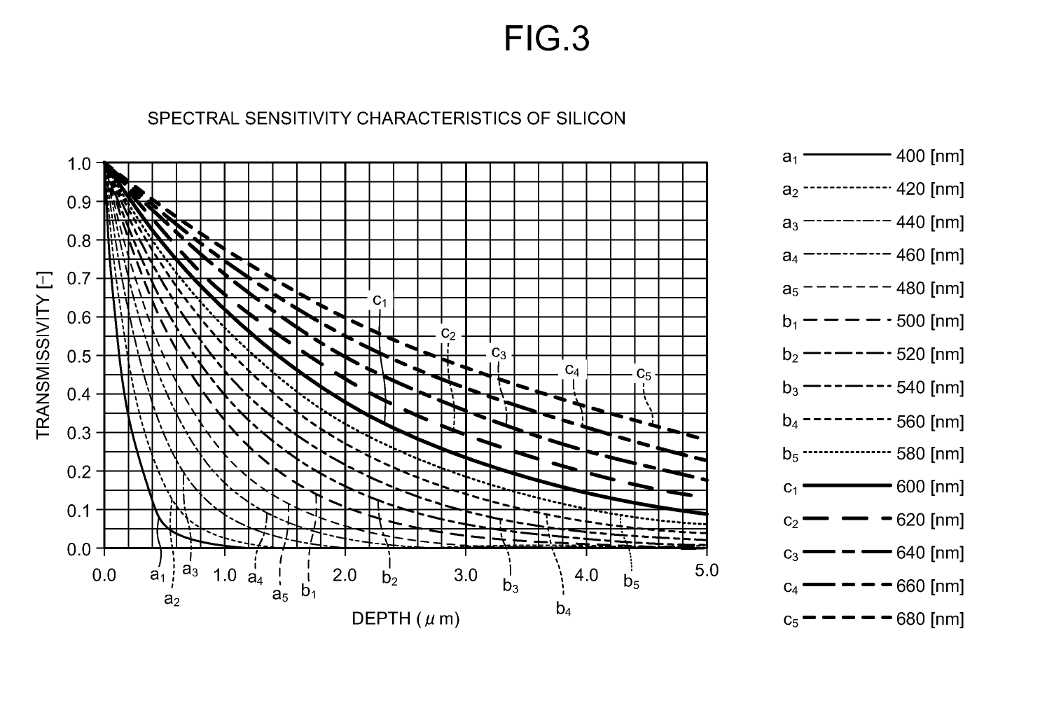

FIG. 3 illustrates spectral sensitivity characteristics of silicon (Si). A horizontal axis indicates a depth (thickness: μm) of the monocrystal silicon substrate 11, and a vertical axis indicates transmissivity. Spectral sensitivity curves are illustrated for 400 nm by a₁, 420 nm by a₂, 440 nm by a₃, 460 nm by a₄, 480 nm by a₅, 500 nm by b₁, 520 nm by b₂, 540 nm by b₃, 560 nm by b₄, 580 nm by b₅, 600 nm by c₁, 620 nm by c₂, 640 nm by c₃, 660 nm by c₄, and 680 nm by c₅. As is apparent from the drawing, Si has a high absorption sensitivity of blue light that is in the wavelength range of wavelength of 500 nm or less due to its band gap structure, however, an absorption sensitivity of red light that is in the wavelength range of wavelength of 600 nm or more is not high.

In a case of using a silicon substrate with a predetermined thickness, it is assumed to have the transmissivity corresponding to the transmissivity at a depth in the horizontal axis. According to FIG. 3, in a case of using Si with a film thickness of 1 μm, for example, it can be understood that light having the wavelength of 420 nm is absorbed by 95%, however, light having the wavelength of 640 nm is absorbed only by 30%.

Thus, by adjusting the film thickness of the first photoelectric conversion unit 10 configured of Si to be thin, a photoelectric conversion unit having the absorption sensitivity to blue light and capable of permeating red light can be formed. The light having permeated through the monocrystal silicon substrate 11 is photoelectrically converted by the second photoelectric conversion unit 20 configured of a material exhibiting a high photoelectric conversion property in a long wavelength region of light with the wavelength of 600 nm or more.

Accordingly, the photoelectric conversion of the light with the wavelength of 500 nm to 600 nm, that is, the green light, is performed in the third photoelectric conversion unit 30. Further, in the first photoelectric conversion unit 10, the photoelectric conversion of light with the wavelength of 300 nm to 500 nm, that is, the blue light, among the light with the wavelength range having permeated is performed. Finally, in the second photoelectric conversion unit 20, the light with the wavelength of 600 nm or more, that is, the red light, having permeated the third photoelectric conversion unit 30 and the first photoelectric conversion unit 10 is photoelectrically converted. Accordingly, reading of a color image is implemented in the solid state imaging device of the embodiment.

Next, effects of the first embodiment will be described in detail. In the solid state imaging device of the embodiment, the photoelectric conversion of both the blue light having the short wavelength and the red light having the long wavelength is not performed inside Si such as the monocrystal silicon substrate 11, but only the photoelectric conversion of the blue light having the short wavelength is performed inside the monocrystal silicon substrate 11. Further, light signals with the wavelength excluding the blue light absorbed by the first photoelectric conversion unit 10 are photoelectrically converted in the second photoelectric conversion unit 20 provided on the second principal surface 11B side opposing the side of the first principal surface 11A that is the light receiving surface.

That is, the light having entered from the side of the first principal surface 11A that is the light receiving surface firstly has its wavelength range component with the wavelength of 500 nm to 600 nm photoelectrically converted in the third photoelectric conversion unit 30. Then, only the photoelectric conversion of the blue light of 300 nm to 500 nm that is of the short wavelength is performed inside the monocrystal silicon substrate 11 that is the first photoelectric conversion unit 10.

Further, the light in the wavelength range other than the wavelength ranges absorbed in the first photoelectric conversion unit 10 and the third photoelectric conversion unit 30, that is, in the long wavelength region of 600 nm or more, is photoelectrically converted in the second photoelectric conversion unit 20.

According to the embodiment, the monocrystal silicon substrate 11 is used as a filter, and the red light that is of the wavelength range of 600 nm or more having permeated through the monocrystal silicon substrate 11 is selectively taken in at the SiGe layer 21 formed by the semiconductor material of a different type from silicon, and is photoelectrically converted. Due to this, the formation thereof can be carried out by using the thin monocrystal silicon substrate 11 of 1 μm or less by the spectral characteristics of silicon. As is apparent from FIG. 3, the light having the wavelength of 420 nm can be absorbed by 95% by the thin monocrystal silicon substrate 11 of 1 μm or less. Thus, R and B color mixture hardly occurs, thinning becomes possible, and refining also becomes possible.

With respect to this, in a case of laminating plural photoelectric conversion units which have defferent sensitivity for wavelength ranges each other inside a silicon substrate, a photoelectric conversion unit for extracting light signals with the short wavelength needs to be formed on a light incident surface side, and a photoelectric conversion unit for extracting light signals with the long wavelength needs to be formed therebelow. In an ordinary image sensor, a silicon substrate with a thickness of about 3 μm is used, however, an absorption rate on a long wavelength side is merely about 50% with such a thickness as illustrated in FIG. 3. Thus, in such a device structure, the photoelectric conversion unit for extracting the light on the long wavelength side cannot obtain sufficient signal intensity. Due to this, in the structure that laminates the photoelectric conversion units for the short wavelength range and the long wavelength range within the silicon substrate as above, the silicon film thickness needs to be at a thickness of about 4 μm to 8 μm to reduce R and B color mixture.

In order to form the photoelectric conversion units by using ion injection in a substrate with the thickness of about 4 μm to 8 μm, a special hard mask having a thickness of 4 μm to 8 μm becomes necessary. Due to this, an increase in process cost is inevitable. Further, since the special hard mask having the thickness of about 4 μm to 8 μm needs to be processed, refining of pixel pitch is also difficult.

On the other hand, these problems can be solved by employing the device structure of the embodiment that forms the photoelectric conversion units with differing materials on a back surface side of the substrate. In the device structure of the embodiment, since the structure that receives the light with the long wavelength having the wavelength of 600 nm or more, which Si has difficulty absorbing, with the photoelectric conversion unit using another material is employed, the Si film thickness can be suppressed to 1.5 μm or less, and preferably 1 μm or less. In this case, the formation of the first photoelectric conversion unit 10 configured of Si can be performed by ion injection using a resist mask that utilizes lithography, and since the laminated structure as in the conventional structure is not employed, the increase in the process cost can be inhibited.

Further, since there is no need to process the thick special hard mask, it becomes easy to refine the pixels. Moreover, the second photoelectric conversion unit 20 configured of the material exhibiting the high photoelectric conversion property in the long wavelength region for the light wavelength of 600 nm or more is capable of realizing red light sensitivity equaling that with the thickness that cannot be implemented by a Si substrate. Accordingly, it is possible to relatively reduce R and B color mixture, which had been the problem with the conventional device structure.

According to the above, the photoelectric conversion units in the solid state imaging device of the embodiment is configured of the first photoelectric conversion unit 10 configured of the monocrystal silicon substrate 11, the second photoelectric conversion unit 20 formed on the second principal surface 11B side of the monocrystal silicon substrate 11 and provided with the second photoelectric conversion layer exhibiting the high photoelectric conversion property in the long wavelength region with the light wavelength of 600 nm or more, the third photoelectric conversion unit 30 provided with the third photoelectric conversion layer formed of the organic film 31 exhibiting the high photoelectric conversion effect to the light with the wavelength of 500 nm to 600 nm, and the interlayer insulating films 40 formed between the respective photoelectric conversion units. The first photoelectric conversion unit 10 that photoelectrically converts the light having permeated the third photoelectric conversion unit 30 configured of the organic film 31 can be configured with a thickness of 0.1 μm to 1.5 μm by using the monocrystal silicon substrate 11. If the thickness is less than 0.1 μm, it is difficult to sufficiently obtain an output of the short wavelength range by sufficiently absorbing the light of the short wavelength range. Further, since its effect as a filter also becomes insufficient, it becomes difficult to realize the sufficient reduction of the R and B color mixture. Further, if the thickness of the monocrystal silicon substrate 11 exceeds 1.5 μm, the sufficient reduction of the R and B color mixture also becomes difficult to realize due to the absorption on the long wavelength side with the wavelength of 600 nm or more becoming larger.

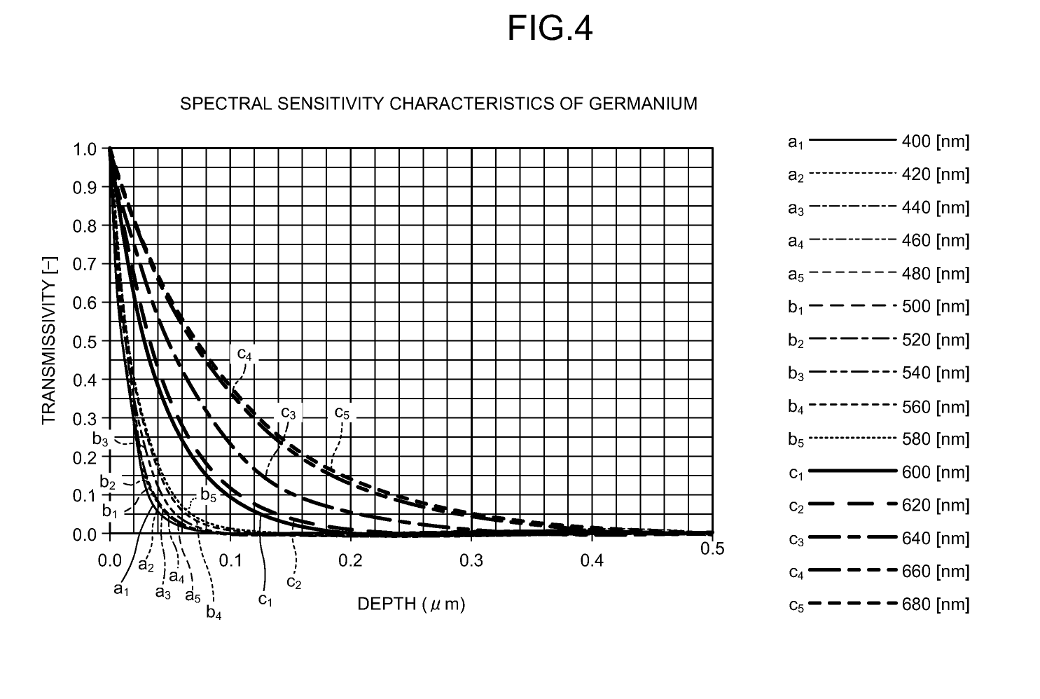

Notably, the second photoelectric conversion unit 20 configured of the material exhibiting the high photoelectric conversion property in the long wavelength region of the wavelength of 600 nm or more that photoelectrically converts the light having permeated the monocrystal silicon substrate 11 is not limited to SiGe, and other materials may be used. For example, Ge that is a material having a narrower band gap than Si, and compound semiconductors such as SiGe, and CdS, CICS and the like used in a solar battery and the like may be used. The thickness will depend on the material, however, in the case of Ge, the thickness may be at about 10 nm to 500 nm. For example, spectral sensitivity characteristics in the case of using Ge is illustrated in FIG. 4. Since the thickness of 6 μm or more is required in order to absorb about 90% of the light having the wavelength of 600 nm or more by using Si, a deep impurity diffusion layer needs to be formed. However, in the case of using Ge, as illustrated in FIG. 4, about 90% can be absorbed with the thickness of 100 nm.

Further, it is possible to use a Ge substrate as the first photoelectric conversion unit 10. In the case of using Ge, as illustrated in FIG. 4, about 90% can be absorbed with the thickness of 100 nm. That is, the first photoelectric conversion unit 10 for the short wavelength range can be formed by using the Ge layer with the thickness of 100 nm, and the second photoelectric conversion unit 20 for the long wavelength range of 600 nm or more can be configured by silicon germanium. As illustrated in FIG. 4, the light in a middle wavelength range of 500 nm to 600 nm is absorbed by the Ge layer, however, the light in the wavelength range of 500 nm to 600 nm that has reached the light receiving surface is mostly absorbed by the third photoelectric conversion unit 30 by configuring the third photoelectric conversion unit 30 by arranging the organic film 31 on the side of the first principal surface 11A that is the light receiving surface. That is, the green light is separated. Then, the light of the short wavelength of 300 nm to 500 nm and the light of the long wavelength of 600 nm or more reach the first photoelectric conversion unit 10, and the light of the short wavelength of 300 nm to 500 nm is photoelectrically converted selectively by the first photoelectric conversion unit 10. Then, the remaining light in the long wavelength range of 600 nm or more may be photoelectrically converted by a silicon germanium layer 21 and the like configuring the second photoelectric conversion unit 20. In this case, the second photoelectric conversion unit 20 may be configured of a semiconductor substrate, the first photoelectric conversion unit 10 may be a thin Ge layer deposited by a CVD method and the like, and the third photoelectric conversion unit 30 may be an organic film formed by an application method. An example that used Ge as the first photoelectric conversion unit 10 will be described later in a fifth embodiment.

### Second Embodiment

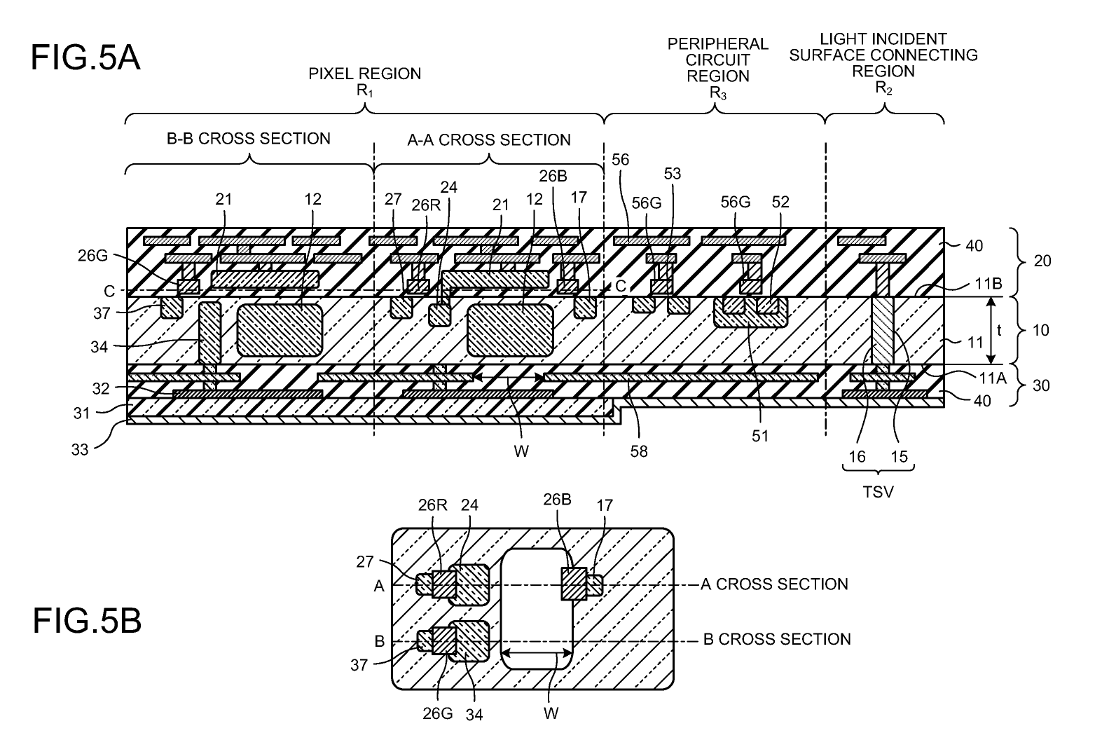

FIGS. 5A and 5B are a cross sectional diagram and a planar diagram schematically illustrating a configuration of a solid state imaging device of a second embodiment. R₁ is a pixel region, R₂ is a light incident surface connecting region, and R₃ is a peripheral circuit region. An A-A cross section in FIG. 5B corresponds to a right-side portion of the pixel region R₁, and a B-B cross section in FIG. 5B corresponds to a left-side portion of the pixel region R₁. Notably, FIG. 5B is the planar diagram seen from a C-C surface in FIG. 5A. A device structure for actually implementing the solid state imaging device of which basic structures of the photoelectric conversion unit had been described in the first embodiment will be described. As illustrated in FIG. 5A, the solid state imaging device of the embodiment has a device structure of a back surface illumination type. That is, a p type monocrystal silicon substrate 11 with a thickness of about 1 μm is used as a semiconductor substrate, and devices configuring a signal processing circuit and wiring sections are formed on a second principal surface 11B positioned on an opposite surface side of a first principal surface 11A that is a light receiving surface. Further, similar to the photoelectric conversion unit of the solid state imaging device of the first embodiment, it is provided with a first photoelectric conversion unit 10 that uses the monocrystal silicon substrate 11 as a first photoelectric conversion layer, a second photoelectric conversion unit 20 formed on the second principal surface 11B side and uses a silicon germanium (SiGe) layer 21 as a second photoelectric conversion layer, and a third photoelectric conversion unit 30 that uses an organic film 31 formed of quinacridone applied to a first principal surface 11A side as a third photoelectric conversion layer, and intervals between the respective photoelectric conversion units are covered by interlayer insulating films 40 such as silicon oxide films.

That is, on the first principal surface 11A side, quinacridone as the organic film 31 exhibiting a high photoelectric conversion effect on light with wavelength of 500 nm to 600 nm, a transparent conductive film as a lower electrode (first electrode) 32, a transparent conductive film as an upper electrode (second electrode) 33, a light shielding electrode 58 configured of a light shielding conductive film connecting the above, and an interlayer insulating film 40 configured of an insulating material such as silicon oxide layer therebetween are formed. The light shielding electrode 58 configured of the light shielding conductive film has a pattern with a window W, which defines a light receiving region. The light shielding electrode 58 is not only a single layer, but may be configured of plural layers, and projection images may configure the window W.

Notably, in a case of employing a sandwich type sensor structure that sandwiches a photoelectric conversion film such as the organic film 31 by the first and second electrodes 32, 33, since a photoelectric conversion efficiency of the photoelectric conversion unit depends on an area of the organic film 31 sandwiched by the first and second electrodes 32, 33, the first and second electrodes 32, 33, preferably are formed so that an opposing portion thereof becomes as large as possible in its area.

Further, the second photoelectric conversion unit 20 that uses the silicon germanium layer 21 as its photoelectric conversion layer and exhibits high photoelectric conversion effect to light on the long wavelength side of 600 nm or more is formed on a second principal surface 11B side. Further, wirings 56 connecting devices configuring a signal processing circuit formed on the monocrystal silicon substrate 11 and an interlayer insulating film 40 therebetween are formed on the second principal surface 11B side.

Further, a photo diode 12 having high sensitivity to light with the short wavelength of 300 nm to 500 nm and configuring the first photoelectric conversion unit 10 is provided inside the monocrystal silicon substrate 11. The photo diode 12 is formed of an n type impurity region, and forms a pn junction with the p type monocrystal silicon substrate 11. Charges corresponding primarily to blue light that had been photoelectrically converted in the photo diode 12 are configured to be transferred to a first floating diffusion 17 via a first transfer gate 26B formed on the second principal surface 11B of the monocrystal silicon substrate 11.

Further, also for charges corresponding primarily to red light that had been photoelectrically converted in the silicon germanium layer 21 configuring the second photoelectric conversion unit 20, the charges are configured to be transferred from a second charge accumulating section 24 formed on the second principal surface 11B of the monocrystal silicon substrate 11 and configured of an n type impurity region to a second floating diffusion 27 configured of an n type impurity region via a second transfer gate 26R formed on the second principal surface 11B.

Yet further, also for charges corresponding primarily to green light that had been photoelectrically converted in the organic film 31 configuring the third photoelectric conversion unit 30, the charges are configured to be transferred from a third charge accumulating section 34 formed on the first principal surface 11A of the monocrystal silicon substrate 11 so as to reach the vicinity of the second principal surface 11B and configured of an n type impurity region to a third floating diffusion 37 configured of an n type impurity region via a third transfer gate 26G formed on the second principal surface 11B.

Further, the second electrode 33 covering an entire surface of the third photoelectric conversion unit 30 is connected to the wiring 56 of the second principal surface 11B via a silicon penetrating electrode TSV configured of a silicon pillar 16 of a polycrystal silicon layer that is filled in a through hole 15 penetrating from the first principal surface 11A to the second principal surface 11B in the light incident surface connecting region R₂.

In the peripheral circuit region R₃, semiconductor devices such as a p channel transistor configured of a p type source/drain region 52 formed in an n well 51 and a gate electrode 56G, and an n channel transistor configured of an n type source/drain region 53 formed in the p type monocrystal silicon substrate 11 and a gate electrode 56G are provided, and configure the signal processing circuit including a reset transistor, an amplifier transistor, an address selection transistor and the like.

Next, an operation of the solid state imaging device will be briefly described. The photo diode 12 configuring the first photoelectric conversion unit 10 is provided in the pixel region R₁ of the p type monocrystal silicon substrate 11, and includes a charge accumulating region configured of the n type impurity region, and a p type impurity region (not illustrated) that is provided on a surface and accumulates holes. Such a photo diode 12 is a photo diode provided with the charge accumulating region that is the n type impurity region that forms the pn junction with the p type monocrystal silicon substrate 11 and the p type impurity region that is a hole accumulating layer, and it photoelectrically converts the incident light entering from a micro lens not illustrated into electrons at an amount corresponding to a quantity of the light, and accumulates the same in the charge accumulating region (photo diode 12).

The first transfer gate 26B functions as a gate that transfers electrons from the photo diode 12 to the first floating diffusion 17 when a predetermined gate voltage is applied. The first floating diffusion 17 temporarily retains the electrons transferred from the photo diode 12.

The second photoelectric conversion unit 20 uses the silicon germanium layer 21 provided on the second principal surface 11B that corresponds to a back surface side of the monocrystal silicon substrate 11 via the interlayer insulating film 40 as the photoelectric conversion layer. Here, the incident light with the wavelength of 600 nm or more that had reached the silicon germanium layer 21 by permeating through the p type monocrystal silicon substrate 11 is photoelectrically converted into electrons at an amount according to a quantity of the light, and is accumulated in the second charge accumulating section 24 configured of the n type impurity region provided in the pixel region R₁ of the monocrystal silicon substrate 11.

The second transfer gate 26R functions as a gate that transfers the electrons from the second charge accumulating section 24 to the second floating diffusion 27 when a predetermined gate voltage is applied. The second floating diffusion 27 temporarily retains the electrons generated in the silicon germanium layer 21 that is the second photoelectric conversion layer and transferred therefrom.

The third photoelectric conversion unit 30 uses the organic film 31 provided on the first principal surface 11A corresponding to the light receiving surface side of the monocrystal silicon substrate 11 via the interlayer insulating film 40 as the photoelectric conversion layer. Here, the incident light with the wavelength of 500 nm to 600 nm that has entered is photoelectrically converted into electrons at an amount according to a quantity of the light, and is accumulated in the third charge accumulating section 34 configured of the n type impurity region provided in the pixel region R₁ of the monocrystal silicon substrate 11.

The third transfer gate 26G functions as a gate that transfers the electrons from the third charge accumulating section 34 to the third floating diffusion 37 when a predetermined gate voltage is applied. The third floating diffusion 37 temporarily retains the electrons generated in the organic film 31 that is the third photoelectric conversion layer and transferred therefrom.

The signal charges transferred to the first to third floating diffusions 17, 27, 37 are amplified by the amplifier transistor not illustrated in the peripheral circuit region R₃, and are read by a peripheral circuit unit as pixel signals in case where the address selection transistor not illustrated is selected, and are used as brightness information of one pixel upon when a taken image is created.

Accordingly, by using the structure of the embodiment, an image sensor that is capable of obtaining the signals of three colors from one pixel can be implemented. According to the embodiment, similar effects as the first embodiment can be achieved, and similar modifications can be adapted. The monocrystal silicon substrate 11 is used as a filter without additionally forming a filter, and the red light in the wavelength range of 600 nm or more that had permeated the monocrystal silicon substrate 11 is selectively taken in at the silicon germanium layer 21, and is photoelectrically converted. With spectral characteristics of silicon, it can be formed by using a thin monocrystal silicon substrate 11 of 1 μm or less, whereby R and B color mixture hardly occurs, thinning becomes possible, and refining also becomes possible.

### Third Embodiment

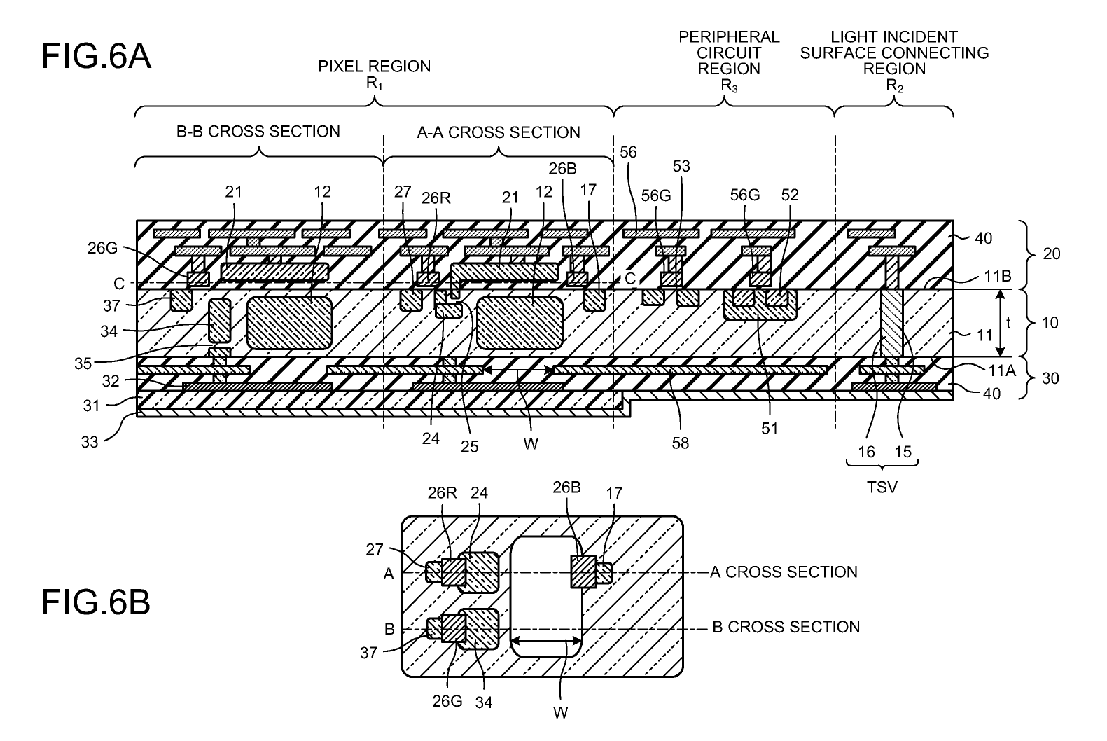

FIGS. 6A and 6B are a cross sectional diagram and a planar diagram schematically illustrating a configuration of a solid state imaging device of a third embodiment. R₁ illustrates a pixel region, R₂ illustrates a light incident surface connecting region, and R₃ illustrates a peripheral circuit region. An A-A cross section in FIG. 6B corresponds to a right-side portion of the pixel region R₁, and a B-B cross section in FIG. 6B corresponds to a left-side portion of the pixel region R₁. Notably, FIG. 6B is the planar diagram seen from a C-C surface in FIG. 6A. The solid state imaging device of the embodiment differs from the solid state imaging device described in the second embodiment in that first and second overflow barriers (Overflow Barriers) 25, 35 respectively configured of low concentration impurity regions are formed in a second charge accumulating section 24 that accumulates charges photoelectrically converted in a silicon germanium layer 21 of a second photoelectric conversion unit 20, and a third charge accumulating section 34 that accumulates charges photoelectrically converted in an organic film 31 of a third photoelectric conversion unit 30. Other parts are identical to the solid state imaging device of the second embodiment and descriptions thereof are omitted, however, same reference signs are given to identical portions.

Here, effects of forming the overflow barriers in the second and third charge accumulating sections 24, 34 will be described. Firstly, the effects in the second photoelectric conversion unit 20 using a photoelectric conversion material exhibiting a high photoelectric conversion effect to light on a long wavelength side of 600 nm or more will be described. In the solid state imaging device of the embodiment, the silicon germanium layer 21 is used as the photoelectric conversion material exhibiting the high photoelectric conversion effect to the light on the long wavelength side. Ge or compound semiconductors such as SiGe, and CdS, CICS and the like used in a solar battery and the like, which are materials having a narrower band gap than Si have larger dark current compared to Si when a reverse bias is applied to a pn junction. In a case of not forming the overflow barriers, since the reverse bias is applied to the pn junction of such a material in order to extract a signal that has been photoelectrically converted, a high dark current component thereof becomes a noise component of the photoelectrically converted signal. However, by providing the first overflow barrier 25 in an accumulating unit, and reading out only a signal that had passed over the first overflow barrier 25 as the photoelectrically converted signal, the second photoelectric conversion unit 20 becomes capable of operating without applying the reverse bias. In the case of operating the second photoelectric conversion unit 20 without applying the reverse bias, the dark current flowing in from the silicon germanium layer 21 is drastically reduced, whereby S/N ratio is improved.

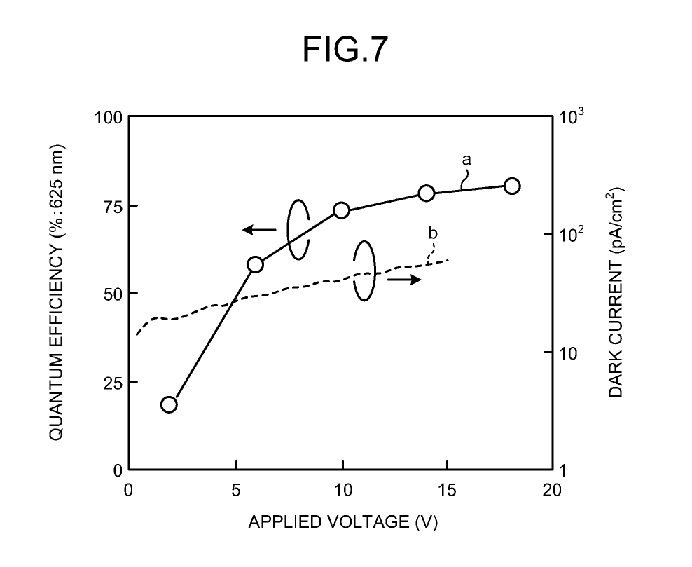

Next, the effects of the organic film 31 formed of quinacridone and configuring the third photoelectric conversion unit 30 exhibiting a high photoelectric conversion effect to light of 500 nm to 600 nm will be described. FIG. 7 is a diagram illustrating characteristics of a photoelectric conversion unit that uses quinacridone as a photoelectric conversion layer, in which ‘a’ is a curve illustrating a relationship of an applied voltage and quantum efficiency (photoelectric conversion efficiency), and ‘b’ is a curve illustrating a relationship of the applied voltage and the dark current. As illustrated in FIG. 7, the organic film 31 has characteristics in which its photoelectric conversion efficiency changes by the bias to be applied. Due to this, in a case of directly connecting the third charge accumulating section 34 and a first electrode 32, there is a problem that linearity of optical sensitivity is deteriorated by a voltage of the first electrode 32 being fluctuated by electrons photoelectrically converted by the organic film 31. With respect to this, as in the solid state imaging device of the embodiment, the change in the bias caused by the photoelectric conversion in the organic film 31 becomes capable of being read out as a signal by providing the second overflow barrier 35 in the third charge accumulating section 34, whereby this problem can be solved.

According to the embodiment, the first and second overflow barriers 25, 35 are provided in the second and third charge accumulating sections 24, 34 in the second and third photoelectric conversion units 20, 30. As a result, in addition to the working effects achieved by the solid state imaging devices of the first and second embodiments, the effect of being able to improve the S/N ratio can be achieved. Further, an output characteristic with high linearity can be obtained.

### Fourth Embodiment

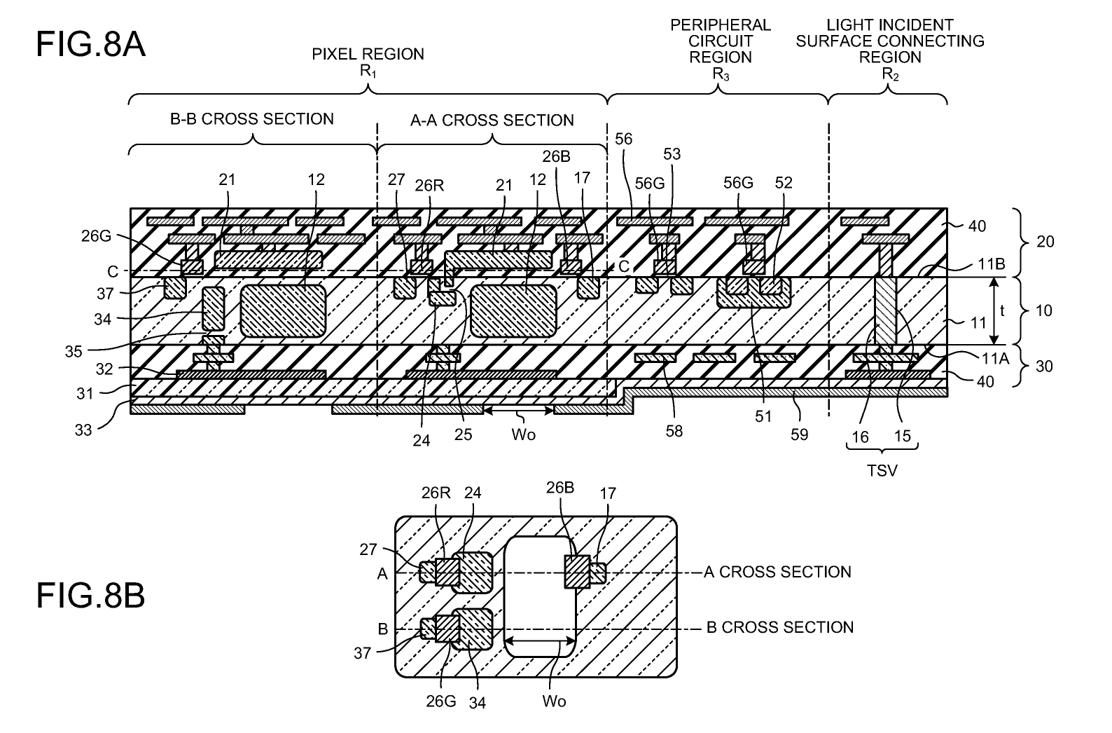

FIGS. 8A and 8B are a cross sectional diagram and a planar diagram schematically illustrating a configuration of a solid state imaging device of a fourth embodiment. R₁ illustrates a pixel region, R₂ illustrates a light incident surface connecting region, and R₃ illustrates a peripheral circuit region. An A-A cross section in FIG. 8B corresponds to a right-side portion of the pixel region R₁, and a B-B cross section in FIG. 8B corresponds to a left-side portion of the pixel region R₁. Notably, FIG. 8B is the planar diagram seen from a C-C surface in FIG. 8A. The solid state imaging device of the embodiment is characteristic in forming a light shielding film 59 formed of a tungsten film on a topmost surface on a first principal surface 11A side that is a light receiving surface side, and defining a light receiving region by a window Wo formed in the light shielding film 59, instead of defining the light receiving region by the light shielding electrode 58 in the solid state imaging device described in the third embodiment. Here, it is different from the solid state imaging device of the third embodiment in that a conductive film configuring the light shielding electrode 58 is a mass having a small-patterned pattern compared to the third embodiment, and directing of wirings is decreased. This is because an electrode pattern is formed in regards to the light shielding electrode 58 without considering the defining of the light receiving region, and the light receiving region is defined by the pattern of the light shielding film 59 on the topmost surface. Other parts are identical to the solid state imaging device of the third embodiment and descriptions thereof are omitted, however, same reference signs are given to identical portions. Here, as the light shielding film 59, it is preferable to use a three-layer structure of titanium, titanium nitride, and tungsten by considering adhesion and barrier performances.

According to the embodiment, the light shielding film 59 is formed on the topmost surface on the light receiving surface side. Due to this, in addition to the working effects achieved by the solid state imaging device of the first to third embodiments, the light receiving region can surely be defined. Further, in the case of configuring the light shielding film 59 by the conductive material, there also is an effect of reducing a current resistance by laminating the same on a second electrode 33 that is a translucent electrode.

Notably, although the light shielding film 59 can be configured of the conductive material such as the tungsten film, it may be formed of an insulating material such as tungsten oxide.

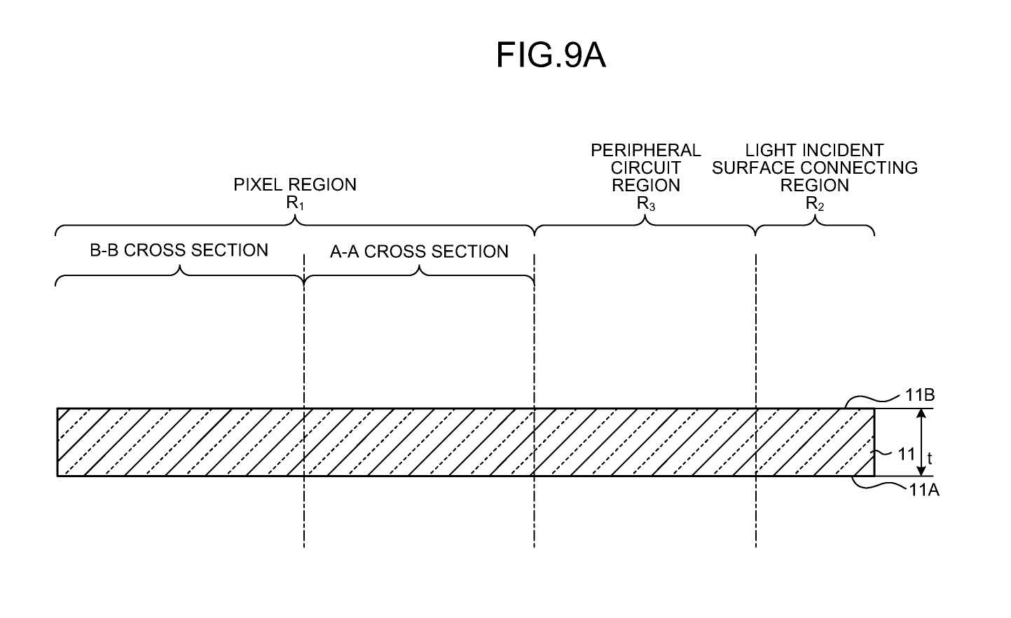

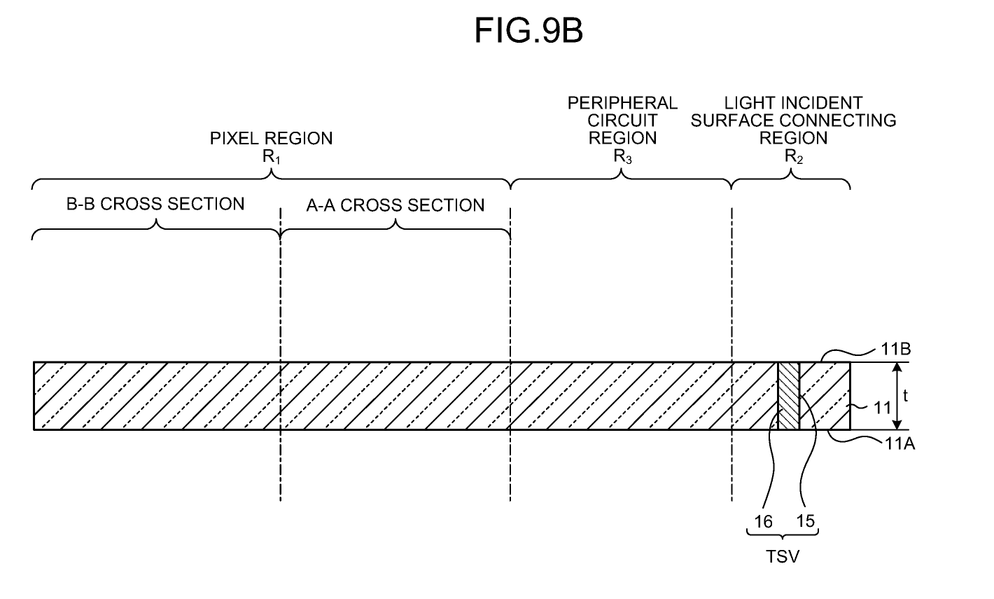

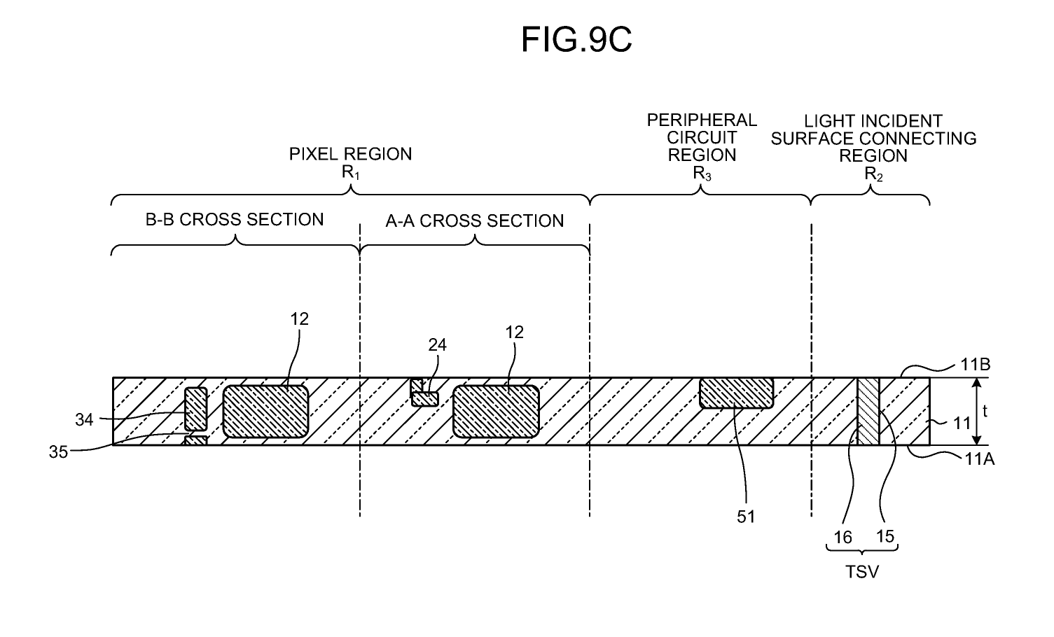

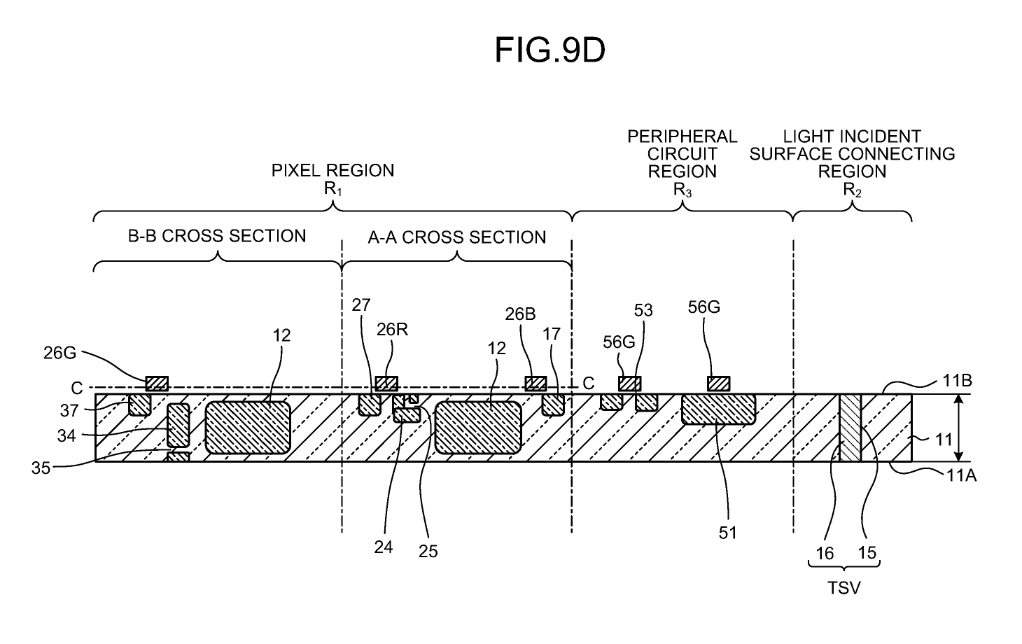

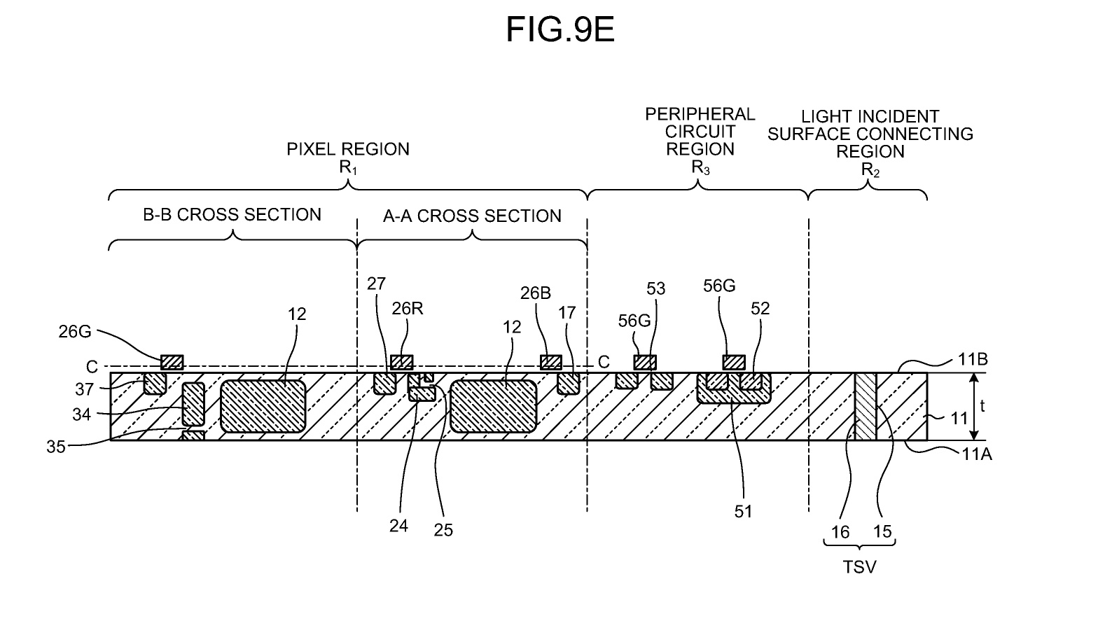

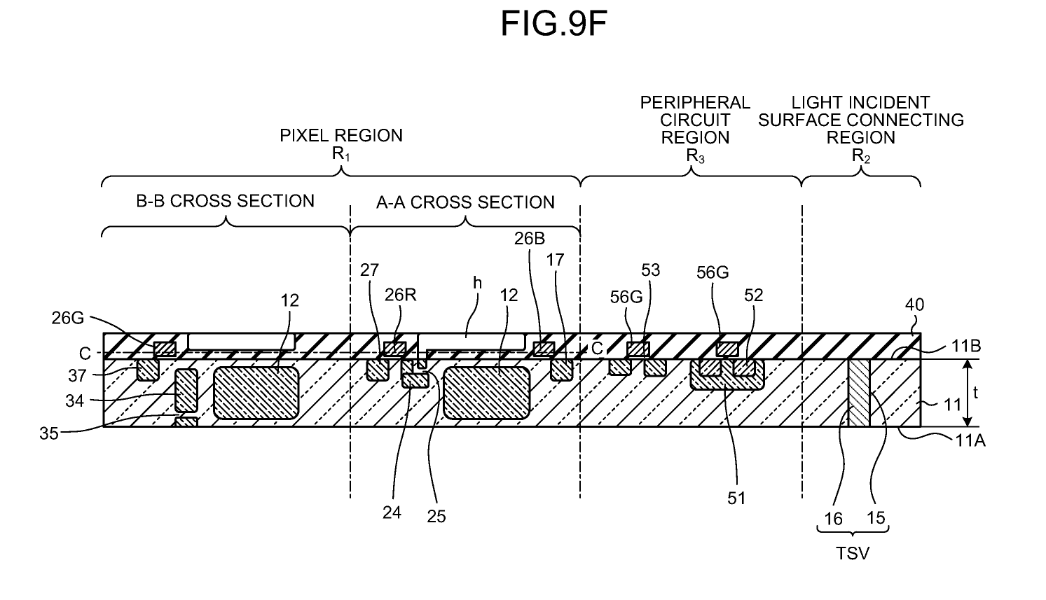

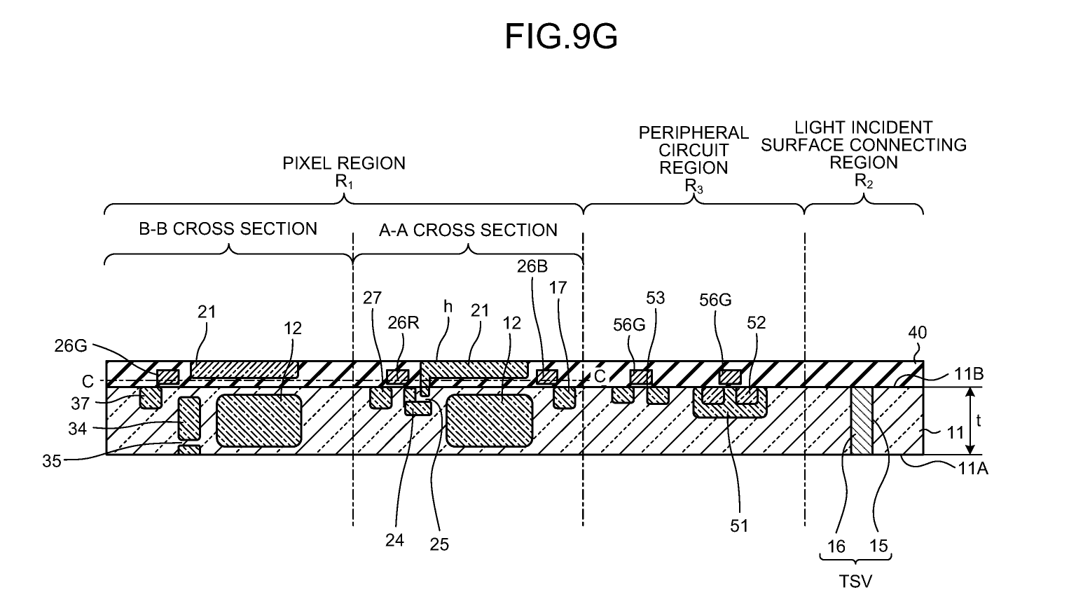

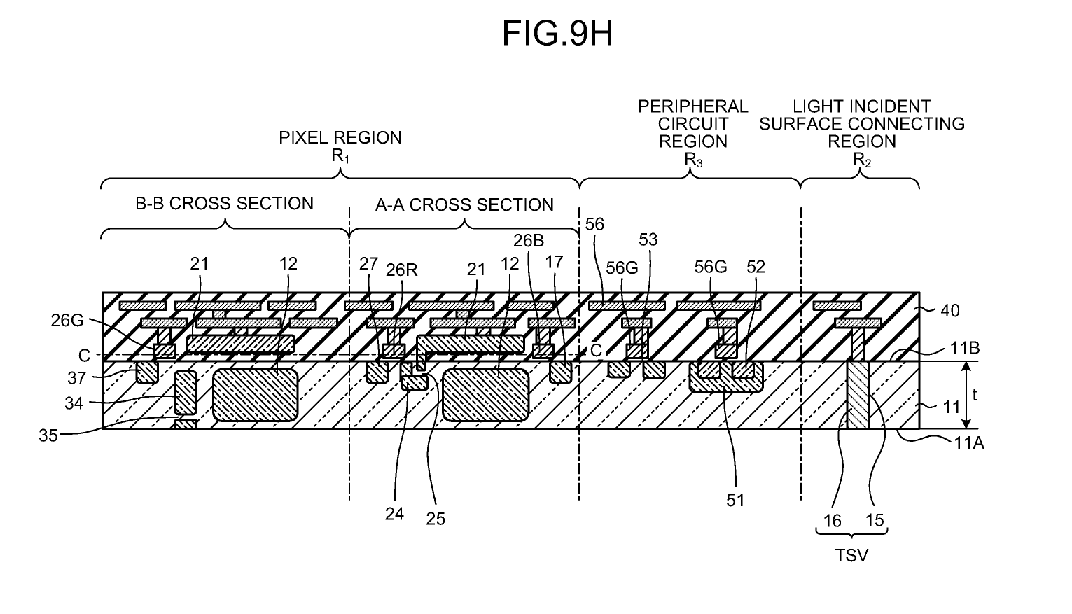

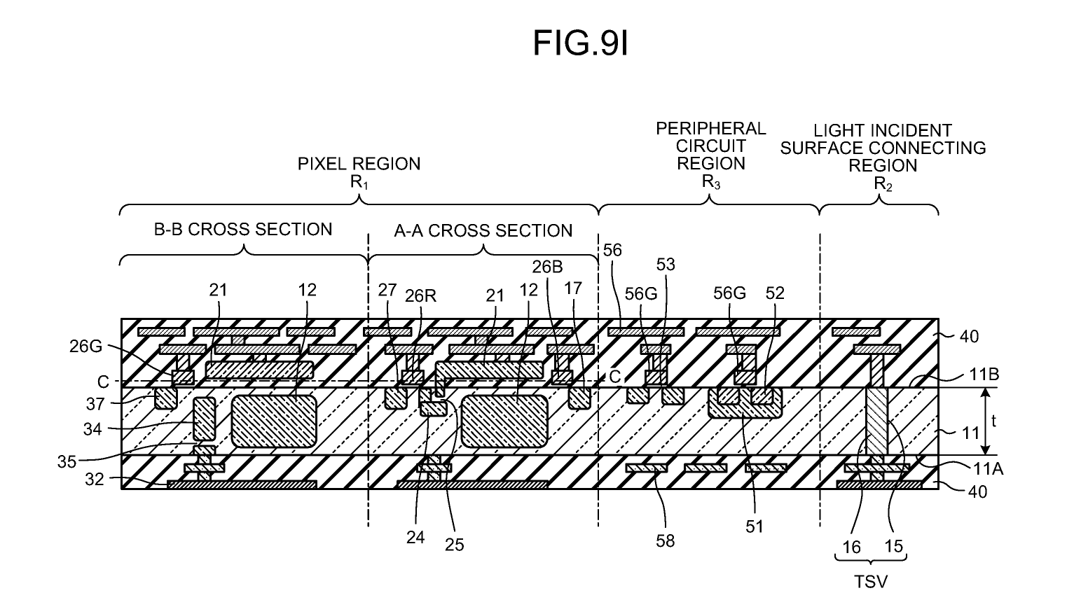

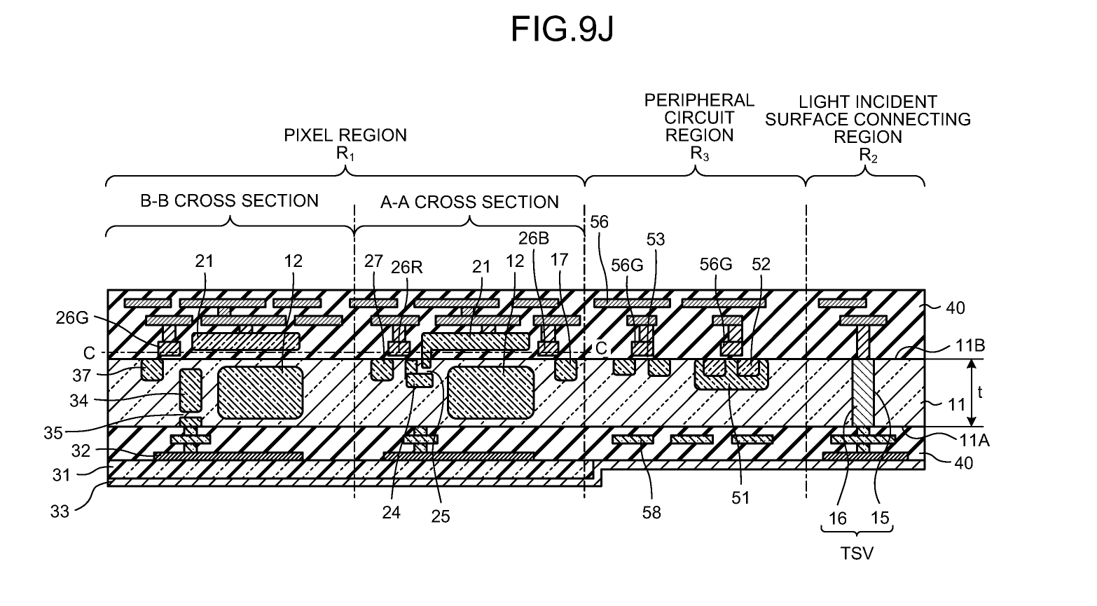

Next, a method of manufacturing the solid state imaging device of the fourth embodiment will be described. FIG. 9A to FIG. 9J are process cross sectional diagrams illustrating manufacturing steps of the solid state imaging device of the fourth embodiment.

In the method of manufacturing the solid state imaging device of the embodiment, firstly, as illustrated in FIG. 9A, a p type monocrystal silicon substrate 11 with a thickness t=1 μm is prepared.

Subsequently, as illustrated in FIG. 9B, a through hole 15 is formed by anisotropic etching in a region that is to be the light incident surface connecting region R₂, a polycrystal silicon layer that is doped at a high concentration is filled therein, a silicon pillar 16 is formed to configure into a silicon penetrating electrode TSV. The silicon penetrating electrode TSV is used for connecting an element of the third photoelectric conversion unit 30 provided at the first principal surface 11A that is the light receiving surface side to a wiring section formed on a second principal surface 11B that is on a back surface side.

Thereafter, as illustrated in FIG. 9C, n type impurities such as phosphorus are injected by ion injection, and thereafter annealing process is performed to form an n well 51, a photo diode 12, a second charge accumulating section 24, and a third charge accumulating section 34. In the formation, since depths and concentrations differ respectively, the above are formed sequentially to be of desired concentrations and depths. Here, as for the third charge accumulating section 34, a second overflow barrier 35 is simultaneously formed.

Next, as illustrated in FIG. 9D, a polycrystal silicon layer is formed on the second principal surface 11B of the monocrystal silicon substrate 11 via a gate insulating film, and a first transfer gate 26B, a second transfer gate 26R, a third transfer gate 26G, and a gate electrode 56G are formed as patterns. Specifically, a thin silicon oxide film with a film thickness of about 5 nm is formed on the second principal surface 11B of the monocrystal silicon substrate 11, and the polycrystal silicon layer with a film thickness of about 150 nm is formed on an upper surface of the silicon oxide film. Thereafter, by performing photolithography and etching, the gate insulating film, the transfer gates, and the gate electrode are formed by removing the polysilicon layer and silicon oxide film at unnecessary portions. Further, n type impurities such as phosphorus are injected by ion injection, and thereafter annealing process is performed to form an n type source/drain region 53, and first to third floating diffusions 17, 27, 37.

After the above, as illustrated in FIG. 9E, p type impurities such as boron are injected by ion injection, and thereafter annealing process is performed to form a p type source/drain region 52 in the n well 51.

Then, as illustrated in FIG. 9F, an interlayer insulating film 40 formed of a silicon oxide film is formed, and an opening h for forming a second photoelectric conversion layer is formed.

Then, as illustrated in FIG. 9G, a silicon germanium layer 21 is formed in the opening h by depositing silicon germanium by a CVD method and performing etchback.

Further, as illustrated in FIG. 9H, an interlayer insulating film 40 formed of a silicon oxide film is formed, and wirings 56 and the like are formed.

Thereafter, as illustrated in FIG. 9I, a wiring section that forms the interlayer insulating films 40, the light shielding electrode 58, and an indium tin oxide (ITO) layer as a first electrode 32 of a third photoelectric conversion layer is adhered on the first principal surface 11A side that is the light receiving surface side. The wiring section is formed on a resin substrate, and the resin substrate is exfoliated after the adhesion.

Finally, as illustrated in FIG. 9J, an organic film 31 configuring the third photoelectric conversion layer is applied by screen printing, and an ITO layer as the second electrode 33 is formed. Then, at last, a tungsten layer that is the light shielding film 59 is formed. Thereafter, by forming an opening by photolithography, a window is formed, and the light receiving region is defined thereby.

Thereafter, optical systems such as an interlayer insulating film, a micro lens (not illustrated), and the like are orderly laminated, and a CMOS image sensor (solid state imaging device) is achieved thereby.

Accordingly, in the method of manufacturing the solid state imaging device of the embodiment, since the formation can be performed by using a thin type silicon substrate, focusing of the photolithography is easy, whereby a highly accurate pattern can be achieved, and it becomes possible to manufacture a solid state imaging device with easy production and with high output performance.

### Fifth Embodiment

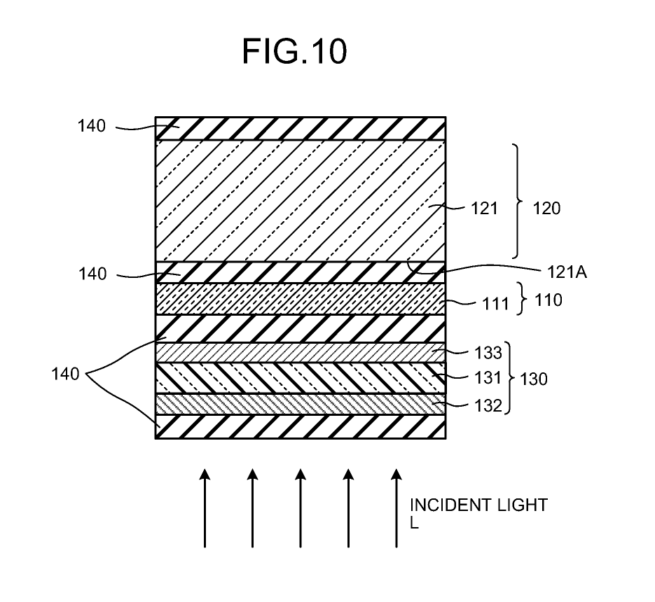

FIG. 10 is a cross sectional diagram schematically illustrating a configuration of a photoelectric conversion unit of a solid state imaging device of a fifth embodiment. Basically, it is similar to the solid state imaging device of the first embodiment, however, the photoelectric conversion unit of the solid state imaging device includes a second photoelectric conversion unit 120 that uses a semiconductor substrate formed of a monocrystal silicon substrate 121 with a thickness of 4 μm as a second photoelectric conversion layer, a first photoelectric conversion unit 110 formed on a side of a first principal surface 121A configuring a light receiving surface of the monocrystal silicon substrate 121 and that uses a germanium (Ge) layer 111 with a thickness of 100 nm that is a semiconductor material of a different type from the semiconductor substrate as a first photoelectric conversion layer, and a third photoelectric conversion unit 130 that uses an organic film 131 that is formed of quinacridone applied via an interlayer insulating film 140 further atop the aforementioned first photoelectric conversion unit 110 as a third photoelectric conversion layer. Further, intervals between the respective photoelectric conversion units are covered by interlayer insulating films 140 such as silicon oxide films.

The third photoelectric conversion unit 130 positioned on the light receiving surface side is similar to the first embodiment, is configured of the organic film 131 sandwiched by first and second electrodes 132, 133, and photoelectrically converts green (G) light with wavelength of 500 nm to 600 nm among light L having entered from the first principal surface 121A side. Further, blue (B) light with wavelength of 300 nm to 500 nm having permeated the third photoelectric conversion unit 130 is selectively absorbed by the first photoelectric conversion unit 110 formed of the germanium layer 111, and photoelectrically converted therein. Further, the first photoelectric conversion unit 110 works as a light filter and removes the light with the wavelength of 300 nm to 500 nm having entered from the first principal surface 121A side and selectively absorbed by the first photoelectric conversion unit 110, and the second photoelectric conversion unit 120 photoelectrically converts red (R) light in a long wavelength region of wavelength of 600 nm or more, selectively.

Here, the first photoelectric conversion unit 110 is configured of the thin germanium layer 111 with a film thickness of 100 nm formed via the interlayer insulating film 140 on the monocrystal silicon substrate 121, and is sandwiched by first and second electrodes that are not illustrated, and is configured capable of extracting signals.

The second photoelectric conversion unit 120 is configured of a photo diode formed in the monocrystal silicon substrate 121, and supports the first photoelectric conversion unit 110 deposited by a CVD method and the like via the interlayer insulating film 140 on the first principal surface 121A. The third photoelectric conversion unit 130 is similar to the first embodiment.

A wiring section that extracts outputs of the first to third photoelectric conversion units 110, 120, 130 and performs signal processing is provided on an opposing surface side of the first principal surface 121A, however, such is omitted herein.

Accordingly, the Ge layer may be used as the first photoelectric conversion unit 110. With Si, light having wavelength of 400 nm can be absorbed up to 90% with a thickness of 400 nm or more. On the other hand, in the case of using Ge, as illustrated in FIG. 4, the absorption of up to 90% can be achieved with a thickness of 100 nm. That is, it is possible to form the first photoelectric conversion unit 110 for a short wavelength range by using the Ge layer with the thickness of 100 nm, and configure the second photoelectric conversion unit 120 for a long wavelength range by the silicon substrate. As illustrated in FIG. 4, the light in the wavelength range of 500 nm to 600 nm is absorbed by the Ge layer, however, by arranging the organic film 131 on the light receiving surface side and configuring the third photoelectric conversion unit 130 by such, most of the light in the wavelength range of 500 nm to 600 nm having reached the light receiving surface is absorbed by the third photoelectric conversion unit 130. That is, the green light is separated. Then, the light in the short wavelength range of 300 nm to 500 nm and the light in a long wavelength range of 600 nm or more reach the first photoelectric conversion unit 110, and only the light in the short wavelength range is photoelectrically converted in the first photoelectric conversion unit 110. Then, the remaining light in the long wavelength range is photoelectrically converted in the silicon and the like configuring the second photoelectric conversion unit 120. In the embodiment, the second photoelectric conversion unit is configured of the semiconductor substrate, the first photoelectric conversion unit 110 is configured of the thin Ge layer deposited by the CVD method and the like, and the third photoelectric conversion unit 130 is configured of the organic film formed by the application method, however, the first photoelectric conversion unit 110 may be formed by a thin germanium substrate, and the second photoelectric conversion unit 120 may be configured of an applied film of a nonorganic film using a different type of semiconductor material.

Notably, the film thickness of the germanium layer 111 is preferably at about 10 nm to 100 nm. A stable film formation is difficult with the thickness less than 10 nm. On the other hand, even if the thickness exceeds 100 nm, there scarcely is any change in absorption efficiency and transmissivity.

According to such a configuration, the second photoelectric conversion unit 120 is the substrate and the first photoelectric conversion unit 110 is configured of the thin film, however, even in this case the blue light can be selectively absorbed by an extremely thin film, whereby R and B color mixture does not occur, and it becomes possible to obtain a solid state imaging device with high reliability.

As for the first to fifth embodiments, the descriptions had been given based on examples including the photoelectric conversion units for three colors, however, it goes without saying that they are applicable to two colors; further, they are also applicable to examples with photoelectric conversion units for four or more colors. Further, the respective configurations can arbitrarily be combined with one another.

The constituent elements of the above-described embodiments can be combined, when the combination can be technically realized. The combination thereof is also included in the embodiments, as long as the combination has the characteristics of the embodiments. It should be apparent to those skilled in the art that various modified examples can be made and the modified examples pertain to the scope of the embodiments.

For example, even when some of the constituent elements are deleted from all of the constituent elements described above in the first to fifth embodiments, if the above-described problem can be resolved, and the above-described advantage can be obtained, the configuration in which the constituent elements are deleted can be realized as the invention. Further, the constituent elements described above in the first to fifth embodiments may be appropriately combined.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid state imaging device comprising:
a semiconductor substrate including a first principal surface configuring a light receiving surface, and a second principal surface opposing the first principal surface; and
a photoelectric conversion unit formed in the semiconductor substrate or above the semiconductor substrate, and configured to photoelectrically convert entered light to signal charges,
wherein the photoelectric conversion unit includes:
a first photoelectric conversion unit that uses at least a part of the semiconductor substrate as a first photoelectric conversion layer; and
a second photoelectric conversion unit that is formed on the second principal surface side of the semiconductor substrate and uses an inorganic semiconductor material that is of a different type from the semiconductor substrate as a second photoelectric conversion layer, and
the second photoelectric conversion unit photoelectrically converts light in a wavelength range having permeated the first photoelectric conversion unit from the first principal surface side.

2. The solid state imaging device according to claim 1, wherein
the photoelectric conversion unit further includes a third photoelectric conversion unit formed on the first principal surface side of the semiconductor substrate and configured of an organic film as a third photoelectric conversion layer.

3. The solid state imaging device according to claim 1, wherein
a second photoelectric conversion film configuring the second photoelectric conversion unit is a compound semiconductor film.

4. The solid state imaging device according to claim 1, further comprising:
a light shielding film formed on the first principal surface side of the semiconductor substrate, and configured to define a light receiving region,
wherein the light shielding film has a conductivity and is electrically connected to a wiring section above the semiconductor substrate.

5. The solid state imaging device according to claim 2, wherein
the semiconductor substrate is a silicon substrate,
the first photoelectric conversion unit is a region that photoelectrically converts light in a wavelength range of blue, and
the second photoelectric conversion unit is a region that photoelectrically converts light in a wavelength range of red.

6. The solid state imaging device according to claim 5, wherein
the third photoelectric conversion unit is a film that photoelectrically converts light in a wavelength range of green.

7. The solid state imaging device according to claim 5, wherein
the silicon substrate has a thickness of 1 μm or less.

8. The solid state imaging device according to claim 1, wherein
the second photoelectric conversion unit is a film containing germanium as a main component.

9. The solid state imaging device according to claim 6, wherein
the third photoelectric conversion unit is an organic film containing quinacridone as a main component.

10. The solid state imaging device according to claim 2, wherein
the semiconductor substrate is provided with a first charge accumulating section that accumulates an output of the second photoelectric conversion unit, and a second charge accumulating section that accumulates an output of the third photoelectric conversion unit.

11. The solid state imaging device according to claim 10, wherein
each of the first and second charge accumulating sections is provided with an overflow barrier.

12. The solid state imaging device according to claim 1, further comprising:
a transfer unit that transfers the signal charges generated in the photoelectric conversion unit from the photoelectric conversion unit to a floating diffusion unit.

13. A solid state imaging device comprising:
a semiconductor substrate including a first principal surface configuring a light receiving surface, and a second principal surface opposing the first principal surface; and
a photoelectric conversion unit formed in the semiconductor substrate or above the semiconductor substrate, and configured to photoelectrically convert entered light to signal charges,
wherein the photoelectric conversion unit includes:
a first photoelectric conversion unit that is formed on the first principal surface side of the semiconductor substrate and uses an inorganic semiconductor material that is of a different type from the semiconductor substrate as a first photoelectric conversion layer; and
a second photoelectric conversion unit that uses at least a part of the semiconductor substrate as a second photoelectric conversion layer, and
the second photoelectric conversion unit photoelectrically converts light in a wavelength range having permeated the first photoelectric conversion unit from the first principal surface side.

14. The solid state imaging device according to claim 13, wherein
the photoelectric conversion unit further includes a third photoelectric conversion unit formed on the first principal surface side of the semiconductor substrate and configured of an organic film as a third photoelectric conversion layer.

15. The solid state imaging device according to claim 14, wherein
the semiconductor substrate is a silicon substrate,
the first photoelectric conversion unit is a region that photoelectrically converts light in a wavelength range of blue, and
the second photoelectric conversion unit is a region that photoelectrically converts light in a wavelength range of red.

16. The solid state imaging device according to claim 15, wherein
the third photoelectric conversion unit is a film that photoelectrically converts light in a wavelength range of green.

17. The solid state imaging device according to claim 13, wherein
the first photoelectric conversion unit is a film containing germanium as a main component.

18. The solid state imaging device according to claim 16, wherein
the third photoelectric conversion unit is an organic film containing quinacridone as a main component.

19. The solid state imaging device according to claim 14, wherein
the first photoelectric conversion unit is formed between the second photoelectric conversion unit and the third photoelectric conversion unit on the first principal surface side.

20. The solid state imaging device according to claim 13, further comprising:
a transfer unit that transfers the signal charges generated in the photoelectric conversion unit from the photoelectric conversion unit to a floating diffusion unit.
